(19) United States
(12) Patent Application Publication
(10) Pub. No.: US 2017/0201274 A1
(43) Pub. Date: Jul. 13, 2017

(54) SECURE MESSAGE DELIVERY IN A DISPERSED STORAGE NETWORK

(71) Applicant: International Business Machines Corporation, Armonk, NY (US)

(72) Inventors: Greg R. Dhuse, Chicago, IL (US); Jason K. Resch, Chicago, IL (US)

(21) Appl. No.: 15/472,458

(22) Filed: Mar. 29, 2017

Related U.S. Application Data
(63) Continuation-in-part of application No. 13/683,951, filed on Nov. 21, 2012.
(60) Provisional application No. 61/564,185, filed on Nov. 28, 2011.

(51) Int. Cl. H03M 13/00; H04L 1/00; H04L 29/08

(52) U.S. Cl. CPC H03M 13/6566; H04L 67/1097; H04L 1/0045; H04L 1/0041

(57) ABSTRACT

A method for sending a secure message within a dispersed storage network (DSN). The method begins with a source computing device sending a notice of a write communication operation to a destination computing device regarding the secure message and sending a set of write communication requests to a set of storage units, wherein the secure message is dispersed storage error encoded into a set of encoded data slices. The method continues by at least some storage units storing at least some encoded data slices in a communication vault. The method continues with the destination computing device sending at least a decode threshold number of write commit communication requests to at least a decode threshold number of storage units of the at some storage units. The method continues by the at least the decode threshold number of storage units sending encoded data slices to the destination computing device.

### CROSS REFERENCE TO RELATED PATENTS

The present U.S. Utility patent application claims priority pursuant to 35 U.S.C. §120 as a continuation-in-part of U.S. Utility application Ser. No. 13/683,951, entitled “PRIORITIZATION OF MESSAGES OF A DISPERSED STORAGE NETWORK”, filed Nov. 21, 2012, which claims priority pursuant to 35 U.S.C. §119(e) to U.S. Provisional Application No. 61/564,185, entitled “OPTIMIZING PERFORMANCE OF DISPERSED STORAGE NETWORK”, filed Nov. 28, 2011, both of which are hereby incorporated herein by reference in their entirety and made part of the present U.S. Utility patent application for all purposes.

### STATEMENT REGARDING FEDERALLY SPONSORED RESEARCH OR DEVELOPMENT

Not applicable.

### INCORPORATION-BY-REFERENCE OF MATERIAL SUBMITTED ON A COMPACT DISC

Not applicable.

### BACKGROUND OF THE INVENTION

Technical Field of the Invention

This invention relates generally to computer networks and more particularly to dispersing error encoded data.

Description of Related Art

Computing devices are known to communicate data, process data, and/or store data. Such computing devices range from wireless smart phones, laptops, tablets, personal computers (PC), work stations, and video game devices, to data centers that support millions of web searches, stock trades, or on-line purchases every day. In general, a computing device includes a central processing unit (CPU), a memory system, user input/output interfaces, peripheral device interfaces, and an interconnecting bus structure.

As is further known, a computer may effectively extend its CPU by using “cloud computing” to perform one or more computing functions (e.g., a service, an application, an algorithm, an arithmetic logic function, etc.) on behalf of the computer. Further, for large services, applications, and/or functions, cloud computing may be performed by multiple cloud computing resources in a distributed manner to improve the response time for completion of the service, application, and/or function. For example, Hadoop is an open source software framework that supports distributed applications enabling application execution by thousands of computers.

In addition to cloud computing, a computer may use “cloud storage” as part of its memory system. As is known, cloud storage enables a user, via its computer, to store files, applications, etc. on an Internet storage system. The Internet storage system may include a RAID (redundant array of independent disks) system and/or a dispersed storage system that uses an error correction scheme to encode data for storage.

### BRIEF DESCRIPTION OF THE SEVERAL VIEWS OF THE DRAWING(S)

FIG. 1 is a schematic block diagram of an embodiment of a dispersed or distributed storage network (DSN) in accordance with the present invention;

FIG. 2 is a schematic block diagram of an embodiment of a computing core in accordance with the present invention;

FIG. 3 is a schematic block diagram of an example of dispersed storage error encoding of data in accordance with the present invention;

FIG. 4 is a schematic block diagram of a generic example of an error encoding function in accordance with the present invention;

FIG. 5 is a schematic block diagram of a specific example of an error encoding function in accordance with the present invention;

FIG. 6 is a schematic block diagram of an example of a slice name of an encoded data slice (EDS) in accordance with the present invention;

FIG. 7 is a schematic block diagram of an example of dispersed storage error decoding of data in accordance with the present invention;

FIG. 8 is a schematic block diagram of a generic example of an error decoding function in accordance with the present invention;

FIG. 9 is a schematic block diagram of an embodiment of sending a secure message in accordance with the present invention;

FIG. 10 is a logic diagram of an example of a method of a 3-phase write operation in accordance with the present invention; and

FIG. 11 is a logic diagram of an example of a method of write communication operation in accordance with the present invention.

### DETAILED DESCRIPTION OF THE INVENTION

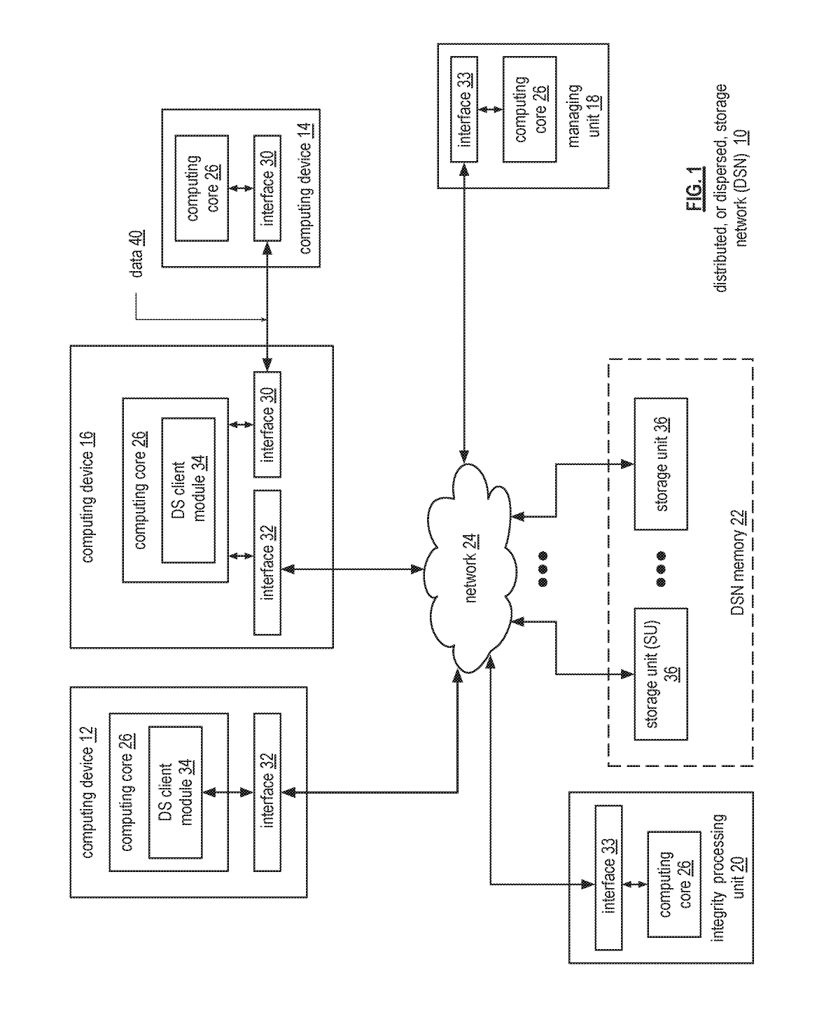

FIG. 1 is a schematic block diagram of an embodiment of a dispersed, or distributed, storage network (DSN) 10 that includes a plurality of computing devices 12-16, a managing unit 18, an integrity processing unit 20, and a DSN memory 22. The components of the DSN 10 are coupled to a network 24, which may include one or more wireless and/or wire lined communication systems; one or more non-public intranet systems and/or public internet systems; and/or one or more local area networks (LAN) and/or wide area networks (WAN).

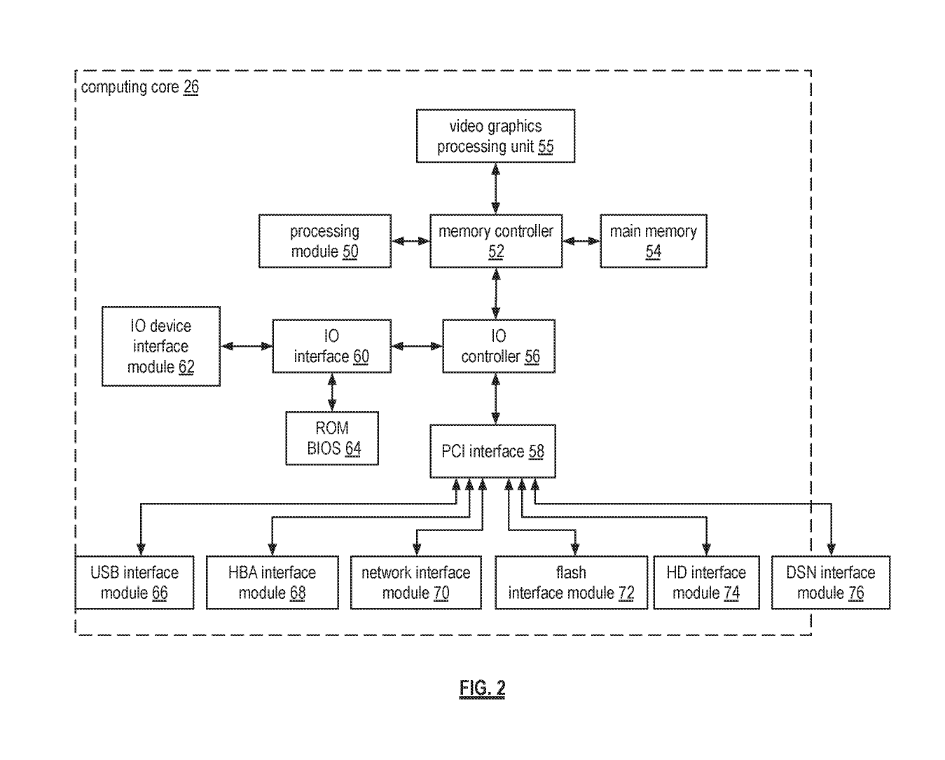

The DSN memory 22 includes a plurality of storage units 36 that may be located at geographically different sites (e.g., one in Chicago, one in Milwaukee, etc.), at a common site, or a combination thereof. For example, if the DSN memory 22 includes eight storage units 36, each storage unit is located at a different site. As another example, if the DSN memory 22 includes eight storage units 36, all eight storage units are located at the same site. As yet another example, if the DSN memory 22 includes eight storage units 36, a first pair of storage units are at a first common site, a second pair of storage units are at a second common site, a third pair of storage units are at a third common site, and a fourth pair of storage units are at a fourth common site. Note that a DSN memory 22 may include more or less than eight storage units 36. Further note that each storage unit 36 includes a computing core (as shown in FIG. 2, or components thereof) and a plurality of memory devices for storing dispersed error encoded data.

Each of the computing devices 12-16, the managing unit 18, and the integrity processing unit 20 include a computing core 26, which includes network interfaces 30-33. Computing devices 12-16 may each be a portable computing device and/or a fixed computing device. A portable computing device may be a social networking device, a gaming device, a cell phone, a smart phone, a digital assistant, a digital music player, a digital video player, a laptop computer, a handheld computer, a tablet, a video game controller, and/or any other portable device that includes a computing core. A fixed computing device may be a computer (PC), a computer server, a cable set-top box, a satellite receiver, a television set, a printer, a fax machine, home entertainment equipment, a video game console, and/or any type of home or office computing equipment. Note that each of the managing unit 18 and the integrity processing unit 20 may be separate computing devices, may be a common computing device, and/or may be integrated into one or more of the computing devices 12-16 and/or into one or more of the storage units 36.

Each interface 30, 32, and 33 includes software and hardware to support one or more communication links via the network 24 indirectly and/or directly. For example, interface 30 supports a communication link (e.g., wired, wireless, direct, via a LAN, via the network 24, etc.) between computing devices 14 and 16. As another example, interface 32 supports communication links (e.g., a wired connection, a wireless connection, a LAN connection, and/or any other type of connection to/from the network 24) between computing devices 12 and 16 and the DSN memory 22. As yet another example, interface 33 supports a communication link for each of the managing unit 18 and the integrity processing unit 20 to the network 24.

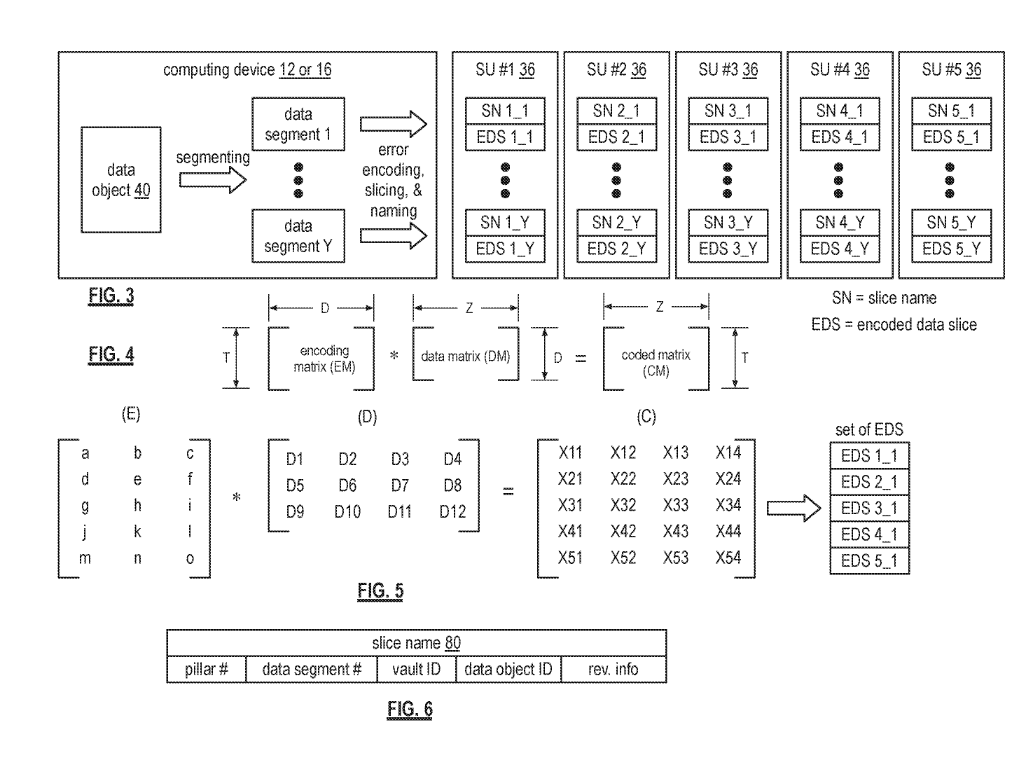

Computing devices 12 and 16 include a dispersed storage (DS) client module 34, which enables the computing device to dispersed storage error encode and decode data (e.g., data 40) as subsequently described with reference to one or more of FIGS. 3-8. In this example embodiment, computing device 16 functions as a dispersed storage processing agent for computing device 14. In this role, computing device 16 dispersed storage error encodes and decodes data on behalf of computing device 14. With the use of dispersed storage error encoding and decoding, the DSN 10 is tolerant of a significant number of storage unit failures (the number of failures is based on parameters of the dispersed storage error encoding function) without loss of data and without the need for a redundant or backup copies of the data. Further, the DSN 10 stores data for an indefinite period of time without data loss and in a secure manner (e.g., the system is very resistant to unauthorized attempts at accessing the data).

In operation, the managing unit 18 performs DS management services. For example, the managing unit 18 establishes distributed data storage parameters (e.g., vault creation, distributed storage parameters, security parameters, billing information, user profile information, etc.) for computing devices 12-14 individually or as part of a group of user devices. As a specific example, the managing unit 18 coordinates creation of a vault (e.g., a virtual memory block associated with a portion of an overall namespace of the DSN) within the DSN memory 22 for a user device, a group of devices, or for public access and establishes per vault dispersed storage (DS) error encoding parameters for a vault. The managing unit 18 facilitates storage of DS error encoding parameters for each vault by updating registry information of the DSN 10, where the registry information may be stored in the DSN memory 22, a computing device 12-16, the managing unit 18, and/or the integrity processing unit 20.

The managing unit 18 creates and stores user profile information (e.g., an access control list (ACL)) in local memory and/or within memory of the DSN memory 22. The user profile information includes authentication information, permissions, and/or the security parameters. The security parameters may include encryption/decryption scheme, one or more encryption keys, key generation scheme, and/or data encoding/decoding scheme.

The managing unit 18 creates billing information for a particular user, a user group, a vault access, public vault access, etc. For instance, the managing unit 18 tracks the number of times a user accesses a non-public vault and/or public vaults, which can be used to generate a per-access billing information. In another instance, the managing unit 18 tracks the amount of data stored and/or retrieved by a user device and/or a user group, which can be used to generate a per-data-amount billing information.

As another example, the managing unit 18 performs network operations, network administration, and/or network maintenance. Network operations includes authenticating user data allocation requests (e.g., read and/or write requests), managing creation of vaults, establishing authentication credentials for user devices, adding/deleting components (e.g., user devices, storage units, and/or computing devices with a DS client module 34) to/from the DSN 10, and/or establishing authentication credentials for the storage units 36. Network administration includes monitoring devices and/or units for failures, maintaining vault information, determining device and/or unit activation status, determining device and/or unit loading, and/or determining any other system level operation that affects the performance level of the DSN 10. Network maintenance includes facilitating replacing, upgrading, repairing, and/or expanding a device and/or unit of the DSN 10.

The integrity processing unit 20 performs rebuilding of ‘bad’ or missing encoded data slices. At a high level, the integrity processing unit 20 performs rebuilding by periodically attempting to retrieve/list encoded data slices, and/or slice names of the encoded data slices, from the DSN memory 22. For retrieved encoded slices, they are checked for errors due to data corruption, outdated version, etc. If a slice includes an error, it is flagged as a ‘bad’ slice. For encoded data slices that were not received and/or not listed, they are flagged as missing slices. Bad and/or missing slices are subsequently rebuilt using other retrieved encoded data slices that are deemed to be good slices to produce rebuilt slices. The rebuilt slices are stored in the DSN memory 22.

FIG. 2 is a schematic block diagram of an embodiment of a computing core 26 that includes a processing module 50, a memory controller 52, main memory 54, a video graphics processing unit 55, an input/output (TO) controller 56, a peripheral component interconnect (PCI) interface 58, an IO interface module 60, at least one IO device interface module 62, a read only memory (ROM) basic input output system (BIOS) 64, and one or more memory interface modules. The one or more memory interface module(s) includes one or more of a universal serial bus (USB) interface module 66, a host bus adapter (HBA) interface module 68, a network interface module 70, a flash interface module 72, a hard drive interface module 74, and a DSN interface module 76.

The DSN interface module 76 functions to mimic a conventional operating system (OS) file system interface (e.g., network file system (NFS), flash file system (FFS), disk file system (DFS), file transfer protocol (FTP), web-based distributed authoring and versioning (WebDAV), etc.) and/or a block memory interface (e.g., small computer system interface (SCSI), internet small computer system interface (iSCSI), etc.). The DSN interface module 76 and/or the network interface module 70 may function as one or more of the interface 30-33 of FIG. 1. Note that the IO device interface module 62 and/or the memory interface modules 66-76 may be collectively or individually referred to as IO ports.

FIG. 3 is a schematic block diagram of an example of dispersed storage error encoding of data. When a computing device 12 or 16 has data to store it disperse storage error encodes the data in accordance with a dispersed storage error encoding process based on dispersed storage error encoding parameters. The dispersed storage error encoding parameters include an encoding function (e.g., information dispersal algorithm, Reed-Solomon, Cauchy Reed-Solomon, systematic encoding, non-systematic encoding, on-line codes, etc.), a data segmenting protocol (e.g., data segment size, fixed, variable, etc.), and per data segment encoding values. The per data segment encoding values include a total, or pillar width, number (T) of encoded data slices per encoding of a data segment (i.e., in a set of encoded data slices); a decode threshold number (D) of encoded data slices of a set of encoded data slices that are needed to recover the data segment; a read threshold number (R) of encoded data slices to indicate a number of encoded data slices per set to be read from storage for decoding of the data segment; and/or a write threshold number (W) to indicate a number of encoded data slices per set that must be accurately stored before the encoded data segment is deemed to have been properly stored. The dispersed storage error encoding parameters may further include slicing information (e.g., the number of encoded data slices that will be created for each data segment) and/or slice security information (e.g., per encoded data slice encryption, compression, integrity checksum, etc.).

In the present example, Cauchy Reed-Solomon has been selected as the encoding function (a generic example is shown in FIG. 4 and a specific example is shown in FIG. 5); the data segmenting protocol is to divide the data object into fixed sized data segments; and the per data segment encoding values include: a pillar width of 5, a decode threshold of 3, a read threshold of 4, and a write threshold of 4. In accordance with the data segmenting protocol, the computing device 12 or 16 divides the data (e.g., a file (e.g., text, video, audio, etc.), a data object, or other data arrangement) into a plurality of fixed sized data segments (e.g., 1 through Y of a fixed size in range of Kilo-bytes to Tera-bytes or more). The number of data segments created is dependent of the size of the data and the data segmenting protocol.

The computing device 12 or 16 then disperse storage error encodes a data segment using the selected encoding function (e.g., Cauchy Reed-Solomon) to produce a set of encoded data slices. FIG. 4 illustrates a generic Cauchy Reed-Solomon encoding function, which includes an encoding matrix (EM), a data matrix (DM), and a coded matrix (CM). The size of the encoding matrix (EM) is dependent on the pillar width number (T) and the decode threshold number (D) of selected per data segment encoding values. To produce the data matrix (DM), the data segment is divided into a plurality of data blocks and the data blocks are arranged into D number of rows with Z data blocks per row. Note that Z is a function of the number of data blocks created from the data segment and the decode threshold number (D). The coded matrix is produced by matrix multiplying the data matrix by the encoding matrix.

FIG. 5 illustrates a specific example of Cauchy Reed-Solomon encoding with a pillar number (T) of five and decode threshold number of three. In this example, a first data segment is divided into twelve data blocks (D1-D12). The coded matrix includes five rows of coded data blocks, where the first row of X11-X14 corresponds to a first encoded data slice (EDS 1_1), the second row of X21-X24 corresponds to a second encoded data slice (EDS 2_1), the third row of X31-X34 corresponds to a third encoded data slice (EDS 3_1), the fourth row of X41-X44 corresponds to a fourth encoded data slice (EDS 4_1), and the fifth row of X51-X54 corresponds to a fifth encoded data slice (EDS 5_1). Note that the second number of the EDS designation corresponds to the data segment number.

Returning to the discussion of FIG. 3, the computing device also creates a slice name (SN) for each encoded data slice (EDS) in the set of encoded data slices. A typical format for a slice name 80 is shown in FIG. 6. As shown, the slice name (SN) 80 includes a pillar number of the encoded data slice (e.g., one of 1-T), a data segment number (e.g., one of 1-Y), a vault identifier (ID), a data object identifier (ID), and may further include revision level information of the encoded data slices. The slice name functions as, at least part of, a DSN address for the encoded data slice for storage and retrieval from the DSN memory 22.

As a result of encoding, the computing device 12 or 16 produces a plurality of sets of encoded data slices, which are provided with their respective slice names to the storage units for storage. As shown, the first set of encoded data slices includes EDS 1_1 through EDS 5_1 and the first set of slice names includes SN 1_1 through SN 5_1 and the last set of encoded data slices includes EDS 1_Y through EDS 5_Y and the last set of slice names includes SN 1_Y through SN 5_Y.

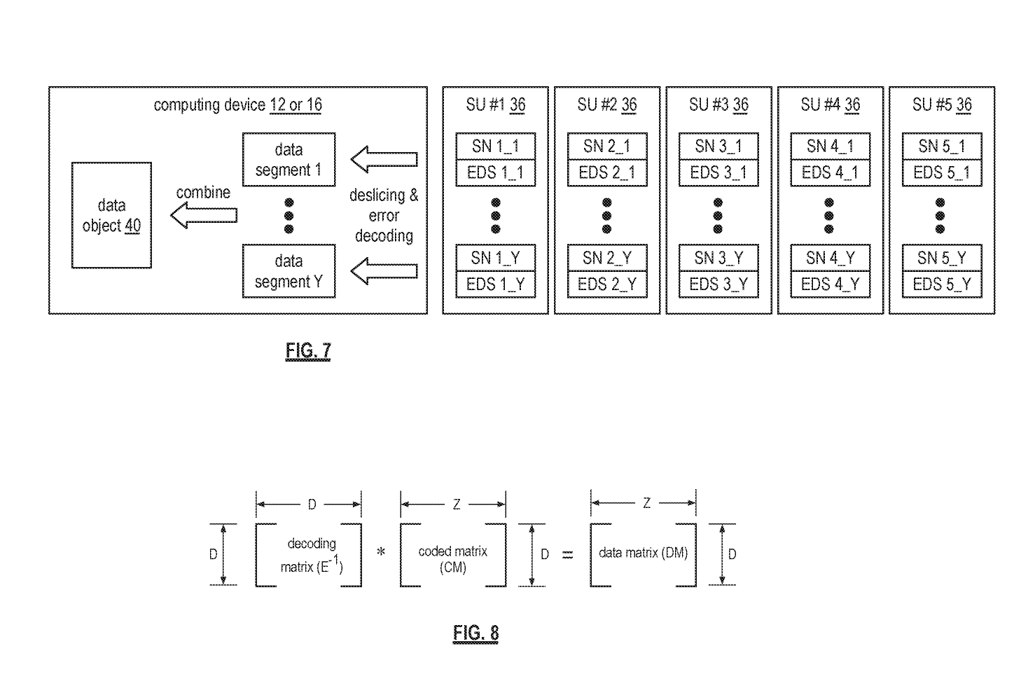

FIG. 7 is a schematic block diagram of an example of dispersed storage error decoding of a data object that was dispersed storage error encoded and stored in the example of FIG. 4. In this example, the computing device 12 or 16 retrieves from the storage units at least the decode threshold number of encoded data slices per data segment. As a specific example, the computing device retrieves a read threshold number of encoded data slices.

To recover a data segment from a decode threshold number of encoded data slices, the computing device uses a decoding function as shown in FIG. 8. As shown, the decoding function is essentially an inverse of the encoding function of FIG. 4. The coded matrix includes a decode threshold number of rows (e.g., three in this example) and the decoding matrix in an inversion of the encoding matrix that includes the corresponding rows of the coded matrix. For example, if the coded matrix includes rows 1, 2, and 4, the encoding matrix is reduced to rows 1, 2, and 4, and then inverted to produce the decoding matrix.

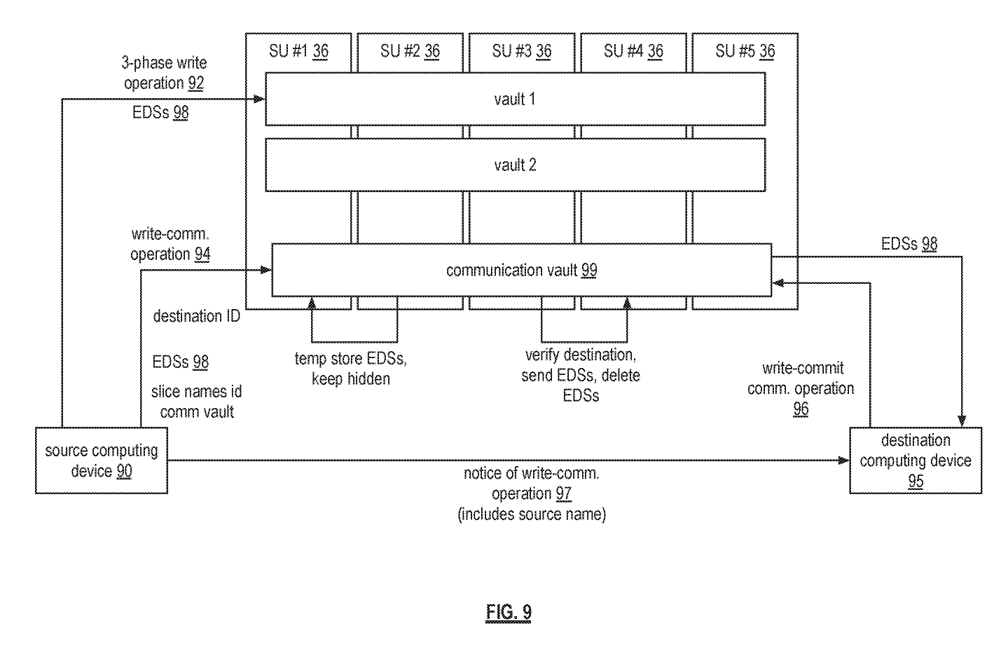

FIG. 9 is a schematic block diagram of an example of a dispersed storage network (DSN), which includes a source computing device 90, a set of storage units 36 (e.g., SUs 36 of FIG. 1), and a destination computing device 95. Both the source and destination computing devices 90 and 95 may be implemented by one of the computing devices 12-16 of FIG. 1. In general, the 3-phase write operation 92 is a function to write data (e.g., encoded data slices (EDSs) 98) to storage units of the DSN for permanent storage. The write communication operation 94 is a communication function for a source computing device 90 to securely send a message to a destination computing device 95 via the storage units 36 of the DSN.

As an example of a 3-phase write operation 92, the source computing device 90 encodes a data object into one or more sets of encoded data slices 98. The source computing device 90 then sends a set of write requests 92 regarding a set of encoded data slices 98 to the set of storage units 36. A write request includes an encoded data slice and its corresponding slice name. As discussed with reference to FIG. 6, the slice name 80 includes a vault ID and a data object ID. The vault ID indicates which vault of the encoded data slice is to be stored (e.g., vault 1 or vault 2).

Upon successful receipt and temporary storage of the encoded data slices, the storage units respond to the source computing device 90 with favorable write responses. At this point, the encoded data slices are stored in the appropriate vault, but are not yet accessible. When the source computing device receives a threshold number of favorable write responses, it sends a set of write commit commands to the storage units, which instructs the storage units to make the encoded data slices accessible. Each of the storage units respond with a favorable write commit response when it has made its encoded data slice accessible.

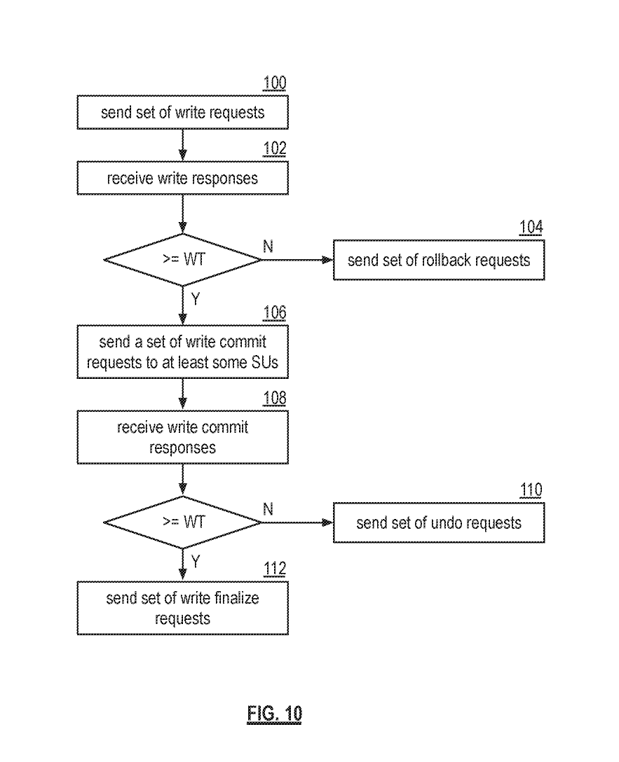

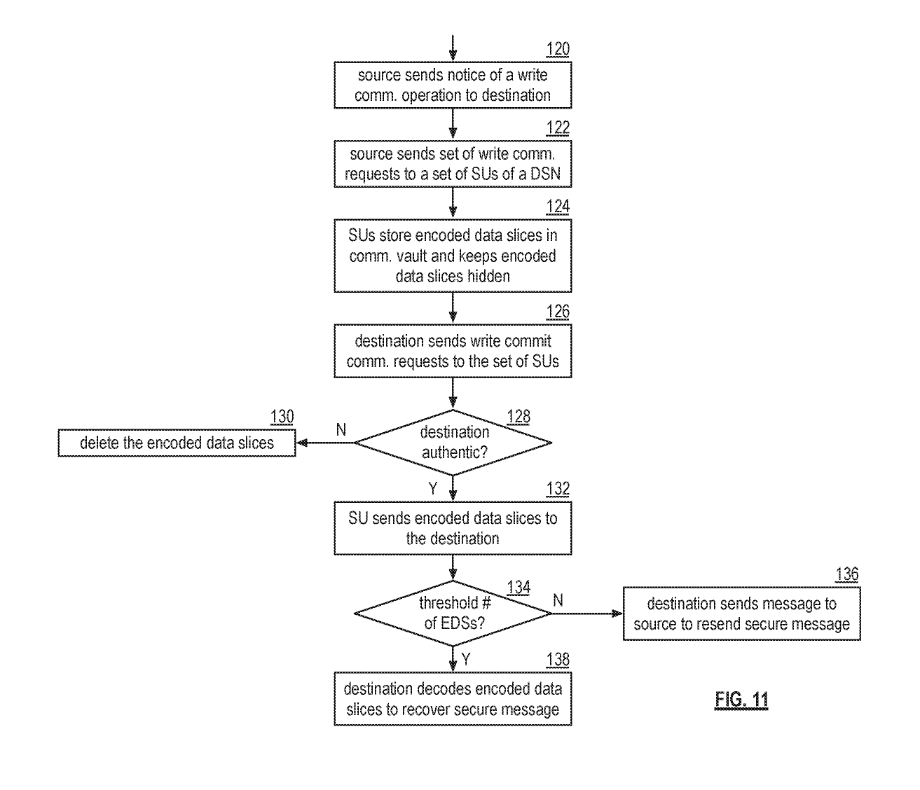

In response to a threshold number of favorable write commit responses, the source computing device 90 sends a set of write finalize requests to the storage units, which instructs the storage units to finalize the writing of the encoded data slices. For example, the finalizing includes updating pointer information for the new set of encoded data slices and what to do with older versions of the encoded data slices. For instance, delete all older versions, keep the previous version, keep the previous two versions, etc. The 3-phase write operation is discussed in greater detail in FIG. 10.

As an example of securely sending a message to a destination computing device 95, the source computing device 90 generates (e.g., creates or receives from another computing device) the secure message. The secure message may be an email, a chat, a file, a telephony, a text, an audio file, a video file, an image, and/or any other type of information. The source computing device 90 then creates a source name (e.g., common portions of the slice name 80) for the secure message. Like creating source names for data to be stored, the source name for a secure communication includes, at least, a vault ID and a data object ID. In this instance, the vault ID is the identification code for the communication vault 99. The devices of the DSN (e.g., computing devices, storage units, managing units, etc.) know that the communication vault is for secure communications and not for long term storage of data.

The source computing device dispersed storage error encodes the message to produce one or more sets of encoded data slices 98 and creates slice names for the slices. The slice names include the source name, which identifies the communication vault, and other information as discussed with reference to FIG. 6. The source computing device sends the set(s) of encoded data slices (or a portion thereof) and an identification code of the destination computing device (e.g., destination ID) to the storage units. The destination ID includes a secret code generated by the source computer, a secure code, an encryption key, a public key of the destination computing device, a user ID, an IP address of the destination computing device, and/or any piece of information to uniquely associate the secure message to the destination computing device or a plurality of destination computing devices. In addition, the source computing device 90 sends a notice 97 of the write communication operation to the destination computing device 95. The notice 97 includes the source name and may further include the destination ID.

As a specific example, the source computing device sends a decode threshold number (or more) of write requests and the destination ID to the storage units. Each write request includes an encoded data slice of the set, a corresponding slice name, and a write operation command. After sending the write requests, the source computing device 90 is finished with the write communication operation (e.g., unlike the write operation it, the source computing device will not send write commit or write finalize requests). Note that the source computing device may receive write responses from the storage units to indicate that the slices have been received and stored in the communication vault.

Upon receiving a write request and the destination ID, a storage unit interprets the write request to determine that it is a secure write-communication operation (e.g., based on the vault ID, based on the destination ID, and/or based on one or more bit settings in the write request) and stores the corresponding encoded data slice in the communication vault 99. Knowing that the encoded data slice is part of a secure write-communication operation, the storage unit keeps the encoded data slice hidden and only accessible to devices that are in possession of the destination ID.

The destination computing device receives the notice of the write-communication operation 97 and stores the destination ID. When the destination computing device 95 is ready to retrieve the message, it sends a set of write commit communication requests 96 to at least a decode threshold number of storage units 36. Once a storage unit 36 receives a write commit communication request 96, it verifies the destination computing device 95. For example, the storage unit verifies that the destination ID (e.g., a secure code) from the destination computing device 95 substantially matches the destination ID (e.g., the secure code) corresponding to the encoded data slice 98 stored in the communication vault 99. When the request is verified, the storage unit sends the requested encoded data slice to the destination computing device.

When the destination computing device 95 receives at least a decode threshold number of encoded data slices 98, it decodes them to recover the secure message. If it does not receive enough encoded data slices 98, the destination computing device 95 determines whether all storage units 36 have been sent a write commit communication request 96. When a write commit communication request 96 was not sent to all storage units, the destination computing device 95 sends one or more new write commit communication requests 96 to storage units 36 which previously were not sent a write communication request 96. When a write commit communication request 96 was sent to all the storage units 36, the destination computing device 95 sends a message to the source computing device 90 to resend the secure message. The write communication operation is discussed in greater detail in FIG. 11.

In an embodiment, the storage units store the set of encoded data slices 98 in the communication vault 99 in accordance with a time (e.g., fixed, until sent to an authorized destination computing device, etc.) or in accordance with other criteria (e.g., for up to a certain number of unauthorized attempts to access the encoded data slices, more than one computing device requests an encoded data slice, upon receiving a security threat message, etc.). For example, the set of storage units store the set of encoded data slices for 1 week, 1 day, 5 hours, or 30 minutes and then it is deleted. As another example, storage units delete encoded data slices from the communication vault when more than one destination computing device requests access. As a further example, storage units maintain storage of slices in vault 1 and vault 2 and deletes slices from the communication vault when they receive a security threat message.

FIG. 10 is a logic flow diagram of a 3-phase write operation. The method begins at step 100, where the source computing device sends a set of write requests regarding storage of a set of encoded data slices to the set of storage units. The method continues at step 102, where the source computing device receives write responses to the set of write requests. Each response is one of a favorable response type (e.g., write succeeded) or an unfavorable response type (e.g., write failed).

When the threshold number of responses to the set of write requests have not been received within the time period (e.g., too many unfavorable responses received), the method continues at step 104, where the source computing device issues a set of rollback requests to the set of storage units to abort storage of the set of encoded data slices. When a threshold number (e.g., a write threshold number) of favorable responses have been received within a time period, the method continues at step 106, where the source computing device issues a set of write commit requests. Each write commit requests instructs a storage unit of the set of storage units to conditionally make available a corresponding encoded data slice of the set of encoded data slices.

The method continues at step 108, where the source computing device receives responses to the set of write commit requests. Each response is one of the favorable response type (e.g., write commit succeeded) and the unfavorable response type (e.g., write commit failed). When a threshold number of responses to the set of write commit requests have not been received within the second time period, the method continues at step 110, where the source computing device issues a set of undo requests to the set of storage units to undo and abort the storage of the set of encoded data slices. When the threshold number (e.g., write threshold number) of responses to the set of write commit requests have been received within a second time period, the method continues at step 112, where the source computing device issues a set of write finalize requests. Each write finalize requests instructs the storage unit to permanently make available the corresponding encoded data slice of the set of encoded data slices. The storage units update storage tables associated with the set of encoded data slices and determines, if necessary, whether to keep previous versions of the set of encoded data slices.

FIG. 11 is a logic flow diagram of a write communication operation in a dispersed storage network (DSN). In the present example, the write communication operation is implemented to send a secure message. The method begins at step 120, where a source computing device of the DSN sends a notice of a write communication operation to a destination computing device of the DSN regarding the secure message. For example, the source computing device sends the notice of the write communication operation to include a source name of the secure message and an indication of a dispersed storage error encoding function, wherein the source name, when converted to a set of slice names for the set of encoded data slices, corresponds to DSN logical addresses within the communication vault.

The method continues at step 122, where the source computing device sends a set of write communication requests to a set of storage units of the DSN. Note the secure message is dispersed storage error encoded into a set of encoded data slices and a first write communication request of the set of write communication request includes a first encoded data slice of the set of encoded data slices and a secure code regarding the destination computing device. For example, the source computing devices sends a write communication request that includes a first encoded data slice and a public key to a storage unit of the set of storage units. Note the secure code may also include one or more of a user name, a subject name, a certificate, a secret key, a fingerprint and a universally unique identifier (UUID).

The method continues with step 124, where at least some of the storage units' store at least some encoded data slices of the set of encoded data slices in a communication vault while keeping the at least some encoded data slices hidden (e.g., not able to be read). For example, a storage unit of the at least some storage units receive a write communication request of the set of write communication requests. The write communication request includes a slice name of the set of slice names and an encoded data slice of the set of encoded data slices. The storage unit interprets the slice name to identify the encoded data slices should be stored in the communication vault and to forego a conventional DSN write operation in favor of the write communication operation and stores the encoded data slice in the communication vault. The encoded data slice is stored in the communication vault in a non-readable manner and without transmitting write responses to the source computing device.

The method continues with step 126, where the destination computing device sends at least a decode threshold number of write commit communication requests to the at least a decode threshold number of storage units of the set of storage units. A write commit communication request of the at least the decode threshold number of write commit communication requests includes a slice name of one of the set of encoded data slices and the secure code. In the present example, the destination computing device generates the set of slice names based on the source name and identifies the set of storage units based on the set of slice names. The destination computing device interprets the decode threshold number based on the indication of the dispersed storage error encoding function.

The method continues with step 128, where a storage unit of the at least the decode number of storage units determines whether the destination communication device is authentic. For example, the storage unit compares the secure code from the destination computing device to the secure code stored in the storage unit and when the comparison is favorable (e.g., destination secure code substantially matches storage unit secure code), the storage unit indicates the destination computing device is authentic.

When a storage unit of the at least the decode threshold number of storage units has not authenticated the destination computing device, the method continues to step 130, where the storage unit deletes the encoded data slice. For example, when the secure code from the destination computing device does not substantially match the secure code stored with the encoded data slice, the storage unit determines the destination computing device is not authentic. Alternatively, the computing device may ask for another secure code from the destination computing device. When the storage unit determines the destination computing device is not authentic, it may delete the stored encoded data slice and may send a message to one or more of other storage units of the set of storage units and the source computing device indicating the destination computing device is not authentic.

When the storage unit of the at least the decode threshold number of storage units has authenticated the destination computing device, the method continues at step 132, where the storage unit sends the encoded data slice to the destination computing device. After sending the encoded data slice, the destination computing device may delete the encoded data slice from the communication vault. The method continues at step 134, where the destination computing device determines whether it has received a decode threshold number of encoded data slices. When the destination computing device has received a decode threshold number of encoded data slices of the set of encoded data slices, the method continues at step 138, where the destination computing device decodes the decode threshold number of encoded data slices to recover the secure message.

When the destination computing device did not receive the decode threshold number of encoded data slices, the destination computing device determines if all storage units of the set of storage units were sent a write commit communication request. If so, the method continues to step 136. If not, the method may loop back to step 126, where the destination computing devices sends one or more other write commit communication requests to other storage units of the set of storage units that were not previously sent a write commit communication request. When the destination computing device is unable to recover the secure message, the method continues at step 136 where the destination computing device sends a message to the source computing device to resend the secure message. For example, when the destination computing device has not received a decode threshold number of encoded data slices and all storage units of the set of storage units have been sent a write communication request, the destination computing device sends a message to the source computing device requesting the secure message to be resent.

It is noted that terminologies as may be used herein such as bit stream, stream, signal sequence, etc. (or their equivalents) have been used interchangeably to describe digital information whose content corresponds to any of a number of desired types (e.g., data, video, speech, audio, etc. any of which may generally be referred to as ‘data’).

As may be used herein, the terms “substantially” and “approximately” provides an industry-accepted tolerance for its corresponding term and/or relativity between items. Such an industry-accepted tolerance ranges from less than one percent to fifty percent and corresponds to, but is not limited to, component values, integrated circuit process variations, temperature variations, rise and fall times, and/or thermal noise. Such relativity between items ranges from a difference of a few percent to magnitude differences. As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1. As may be used herein, the term “compares unfavorably”, indicates that a comparison between two or more items, signals, etc., fails to provide the desired relationship.

As may also be used herein, the terms “processing module”, “processing circuit”, “processor”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, and/or processing unit may be, or further include, memory and/or an integrated memory element, which may be a single memory device, a plurality of memory devices, and/or embedded circuitry of another processing module, module, processing circuit, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, and/or processing unit executes, hard coded and/or operational instructions corresponding to at least some of the steps and/or functions illustrated in one or more of the Figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, and/or any device that stores digital information. The memory device may be in a form a solid state memory, a hard drive memory, cloud memory, thumb drive, server memory, computing device memory, and/or other physical medium for storing digital information.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A method for sending a secure message within a dispersed storage network (DSN), the method comprises:
sending, by a source computing device of the DSN, a notice of a write communication operation to a destination computing device of the DSN regarding the secure message;
sending, by the source computing device, a set of write communication requests to a set of storage units of the DSN, wherein the secure message is dispersed storage error encoded into a set of encoded data slices and wherein a first write communication request of the set of write communication requests includes a first encoded data slice of the set of encoded data slices and a secure code regarding the destination computing device;
storing, by at least some storage units of the set of storage units, at least some encoded data slices of the set of encoded data slices in a communication vault;
sending, by the destination computing device, at least a decode threshold number of write commit communication requests to the at least a decode threshold number of storage units of the set of storage units, wherein a write commit communication request of the at least the decode threshold number of write commit communication requests includes a slice name of one of the set of encoded data slices and the secure code; and
when the at least the decode threshold number of storage units has authenticated the destination computing device, sending, by the at least the decode threshold number of storage units, at least a decode threshold number of encoded data slices of the set of encoded data slices to the destination computing device.

2. The method of claim 1 further comprises:
sending, by the source computing device, the notice of the write communication operation to include a source name of the secure message and an indication of a dispersed storage error encoding function, wherein the source name, when converted to a set of slice names for the set of encoded data slices, corresponds to DSN logical addresses within the communication vault.

3. The method of claim 2, wherein the storing, by a storage unit of the at least some storage units comprises:
receiving a write communication request of the set of write communication requests, wherein the write communication requests includes a slice name of the set of slice names and an encoded data slice of the set of encoded data slices;
interpreting the slice name to identify the communication vault and to forego conventional DSN write operation in favor of the write communication operation; and
storing the encoded data slice in the communication vault.

4. The method of claim 2 further comprises:
generating, by the destination computing device, the set of slice names based on the source name;
identifying, by the destination computing device, the set of storage units based on the set of slice names; and
interpreting, by the destination computing device, the decode threshold number based on the indication of the dispersed storage error encoding function.

5. The method of claim 1, wherein the secure code comprises one or more of:
a user name;
a subject name;
a certificate;
a public key;
a secret key;
a fingerprint; and
a universally unique identifier (UUID).

6. The method of claim 1 further comprises:
storing, by the at least some storage units, the at least some encoded data slices in the communication vault in a non-readable manner without transmitting write responses to the source computing device.

7. The method of claim 1 further comprises:
decoding, by the destination computing device, the at least the decode threshold number of encoded data slices to recover the secure message.

8. The method of claim 1 further comprises:
deleting the at least some encoded data slices of the set of encoded data slices in the communication vault after sending the at least some encoded data slices to the destination computing device.

9. The method of claim 1 further comprises:
when the destination computing device is unable to recover the secure message, sending, by the destination computing device, a message to the source computing device to resend the secure message.

10. A computer readable memory comprises:
a first memory section for storing operational instructions that, when executed by a source computing device, causes the source computing device to send a secure message within a dispersed storage network (DSN) by:
sending a notice of a write communication operation to a destination computing device of the DSN regarding the secure message;
sending a set of write communication requests to a set of storage units of the DSN, wherein the secure message is dispersed storage error encoded into a set of encoded data slices and wherein a first write communication request of the set of write communication requests includes a first encoded data slice of the set of encoded data slices and a secure code regarding the destination computing device;
a second memory section that stores operational instructions that, when executed by at least some storage units of the set of storage units, causes at least some storage units to:
store at least some encoded data slices of the set of encoded data slices in a communication vault;
a third memory section that stores operational instructions that, when executed by the destination computing device, causes the destination computing device to:
send at least a decode threshold number of write commit communication requests to the at least a decode threshold number of storage units of the set of storage units, wherein a write commit communication request of the at least the decode threshold number of write commit communication requests includes a slice name of one of the set of encoded data slices and the secure code; and
a fourth memory section that stores operational instructions that, when executed by the at least the decode threshold number of storage units, causes the at least the decode threshold number of storage units to:
when the at least the decode threshold number of storage units has authenticated the destination computing device, send at least a decode threshold number of encoded data slices of the set of encoded data slices to the destination computing device.

11. The computer readable memory of claim 10, wherein the first memory section further stores operational instructions that, when executing by the source computing device, causes the source computing device to:
send the notice of the write communication operation to include a source name of the secure message and an indication of a dispersed storage error encoding function, wherein the source name, when converted to a set of slice names for the set of encoded data slices, corresponds to DSN logical addresses within the communication vault.

12. The computer readable memory of claim 11, wherein the second memory section further stores operational instructions that, when executing by a storage unit of the at least some storage units, causes the storage unit to:
receive a write communication request of the set of write communication requests, wherein the write communication requests includes a slice name of the set of slice names and an encoded data slice of the set of encoded data slices;
interpret the slice name to identify the communication vault and to forego conventional DSN write operation in favor of the write communication operation; and
store the encoded data slice in the communication vault.

13. The computer readable memory of claim 11, wherein the third memory section further stores operational instructions that, when executing by the destination computing device, causes the destination computing device to:
generate the set of slice names based on the source name;
identify the set of storage units based on the set of slice names; and
interpret the decode threshold number based on the indication of the dispersed storage error encoding function.

14. The computer readable memory of claim 10, wherein the secure code comprises one or more of:
a user name;
a subject name;
a certificate;
a public key;
a secret key;
a fingerprint; and
a universally unique identifier (UUID).

15. The computer readable memory of claim 10, wherein the second memory section further stores operational instructions that, when executed by the at least some storage units, causes the at least some storage units to:
store the at least some encoded data slices in the communication vault in a non-readable manner without transmitting write responses to the source computing device.

16. The computer readable memory of claim 10, wherein the third memory section further stores operational instructions that, when executed by the destination computing device, causes the destination computing device to:
decode the at least the decode threshold number of encoded data slices to recover the secure message.

17. The computer readable memory of claim 10, wherein the fourth memory section further stores operational instructions that, when executed by the at least some storage units, causes the at least some storage units to:
delete the at least some encoded data slices of the set of encoded data slices in the communication vault after sending the at least some encoded data slices to the destination computing device.

18. The computer readable memory of claim 10, wherein the third memory section that further stores operational instructions that, when executed by the destination computing device, causes the destination computing device to:
when the destination computing device is unable to recover the secure message, send a message to the source computing device to resend the secure message.
